(19) United States
(12) Patent Application Publication
(10) Pub. No.: US 2011/0203524 A1
(43) Pub. Date: Aug. 25, 2011

(54) ALD FILM-FORMING APPARATUS AND METHOD OF FABRICATING SEMICONDUCTOR DEVICE

(75) Inventor: Tomohiro UNO, Tokyo (JP)

(73) Assignee: ELPIDA MEMORY, INC, Tokyo (JP)

(21) Appl. No.: 13/028,558

(22) Filed: Feb. 16, 2011

(30) Foreign Application Priority Data
Feb. 19, 2010 (JP) 2010-034841

(51) Int. Cl. C23C 16/455; C23C 16/458

(52) U.S. Cl. 118/730; 118/728; 118/715

(57) ABSTRACT

An atomic layer deposition apparatus includes a reaction chamber, a wafer boat in the reaction chamber, a gas supply system connected to the reaction chamber, a first gas exhaust system connected to the reaction chamber, and a second gas exhaust system connected to the reaction chamber. The gas supply system supplies at least a material gas into the reaction chamber in a deposition process. The gas supply system supplies a purge gas into the reaction chamber in a purging process. The first gas exhaust system performs exhausting operation in the deposition process. The first gas exhaust system is prohibited from performing exhausting operation in the purging process. The second gas exhaust system is prohibited from performing exhausting operation in the deposition process. The second gas exhaust system performs exhausting operation in the purging process.

### BACKGROUND OF THE INVENTION

1. Field of the Invention

The present invention relates to an atomic layer deposition (ALD) film-forming apparatus and a method of fabricating a semiconductor device.

Priority is claimed on Japanese Patent Application No. 2010-034841, Feb. 19, 2010, the content of which is incorporated herein by reference.

2. Description of the Related Art

In recent years, a diameter of a wafer has been increased. Also, an aspect ratio of a step difference on the wafer has been also increased. Hence, it has been difficult to form an insulating film with a uniform thickness on the wafer (a semiconductor substrate). In addition, it has been difficult to secure step coverage in fabrication processes of semiconductor devices.

In view of above mentioned obstacles, as a method for forming films on the wafer, an atomic layer deposition (ALD) method has been adapted to be used in place of a conventional chemical vapor deposition (CVD) method. In the ALD method, a plurality of kinds of gases such as a source gas and an oxidation gas are sequentially supplied onto a wafer surface. The ALD method is known as a process that allows a thin film with a uniform thickness and good step coverage to be formed on the wafer.

On the other hand, since the film formation is performed in an atomic layer unit, the ALD method requires a long time, and thus, low productivity has been serious. With regard to this problem, a batch-type ALD film-forming apparatus is known. The batch-type ALD film-forming apparatus increases the number of wafers to be processed at one time. In this way, processing the numerous wafers at the same time has improved the productivity.

As an example of this apparatus, as shown in FIG. 1 of Japanese Unexamined Patent Application, First Publication, No. JP-A-2008-053326, an apparatus in which a plurality of ejection holes are formed in a gas supply pipe in a reaction chamber is known. The apparatus can supply gas onto surfaces of wafers are held separately from each other in the reaction chamber and arranged to overlap with each other in plain view. The apparatus can exhaust the gas through a vacuum exhaust port installed in the top of the reaction chamber.

Further, in connection with a shape of the exhaust port, Japanese Unexamined Patent Application, Second Publication, No. JP-A-2009-076542 discloses an apparatus in which an exhaust port having the shape of an elongate slit is formed in a portion opposite to a gas supply nozzle in a reaction chamber in order to vacuum-exhaust the reaction chamber. Also, Japanese Unexamined Patent Application, Third Publication, No. JP-A-S60-182130 discloses an apparatus in which a gas supply pipe having a plurality of gas holes is installed in a reaction chamber. The apparatus further includes a gas exhaust pipe provided at a position opposite to the gas supply pipe. Further, Japanese Unexamined Patent Application, Fourth Publication, No. JP-A-H05-211122 discloses an apparatus in which a gas supply pipe and a gas exhaust pipe are opposed to each other in a reaction chamber with reference to a wafer boat. The gas exhaust pipe has gas exhaust ports whose diameters increase as positions of the exhaust ports is getting higher.

Further, in connection with an exhaust system, Japanese Unexamined Patent Application, Fifth Publication, No. JP-A-2004-023043 discloses an apparatus in which a common exhaust system (a first exhaust system) for discharging a source gas, an activation gas, and a purge gas out of a reaction container is installed. Japanese Unexamined Patent Application, Fifth Publication, No. JP-A-2004-023043 further discloses an apparatus in which a flow of gas is controlled by a shielding plate disposed in a reaction chamber. In addition, Japanese Unexamined Patent Application, Fifth Publication, No. JP-A-H01-049218 discloses a vertical CVD apparatus in which each two upper and lower exhaust systems of a reaction chamber include a gas exhaust pipe and a means for regulating a flow rate of exhaust gas.

### SUMMARY

In one embodiment, an atomic layer deposition apparatus may include, but is not limited to, a reaction chamber, a wafer boat in the reaction chamber, a gas supply system connected to the reaction chamber, a first gas exhaust system connected to the reaction chamber, and a second gas exhaust system connected to the reaction chamber. The gas supply system supplies at least a material gas into the reaction chamber in a deposition process. The gas supply system supplies a purge gas into the reaction chamber in a purging process. The first gas exhaust system performs exhausting operation in the deposition process. The first gas exhaust system is prohibited from performing exhausting operation in the purging process. The second gas exhaust system is prohibited from performing exhausting operation in the deposition process. The second gas exhaust system performs exhausting operation in the purging process.

In another embodiment, an atomic layer deposition apparatus may include, but is not limited to, a reaction chamber, a gas supply system, a first gas exhaust system, and a second gas exhaust system. The gas supply system is connected to the reaction chamber. The gas supply system supplies a first gas into the reaction chamber in a first deposition process. The gas supply system supplies a purge gas into the reaction chamber in a purging process following to the first deposition process. The gas supply system supplies a reaction gas into the reaction chamber in a second deposition process following to the purging process. The first gas contains a first material to be reacted with the reaction gas. The first gas exhaust system is connected to the reaction chamber. The first gas exhaust system performing exhausting operations in the first deposition process and a second deposition process respectively. The second deposition process follows to the purging process. The first gas exhaust system is prohibited from performing exhausting operation in the purging process. The second gas exhaust system is connected to the reaction chamber. The second gas exhaust system is prohibited from performing exhausting operation in the first and second deposition processes. The second gas exhaust system performs exhausting operation in the purging process.

In still another embodiment, an atomic layer deposition apparatus may include, but is not limited to, a reaction chamber, a wafer boat, a rotating mechanism, a gas supply system, a first gas exhaust system, and a second gas exhaust system. The wafer boat is in the reaction chamber. The rotating mechanism supports the wafer boat. The rotating mechanism is disposed in the reaction chamber. The gas supply system is connected to the reaction chamber. The gas supply system includes a gas supply nozzle in the reaction chamber. The gas supply system supplies, as a material gas, a reaction gas and a first gas alternatively into the reaction chamber in a deposition process. The first gas contains a first material to be reacted with the reaction gas in the deposition process. The gas supply system supplies a purge gas into the reaction chamber in a purging process. The first gas exhaust system is connected to the reaction chamber. The first gas exhaust system includes a first gas suction nozzle in the reaction chamber. The first gas exhaust system includes a first pump outside the reaction chamber. The first gas suction nozzle is opposite to the gas supply nozzle with reference to the wafer boat. The first gas exhaust system performs exhausting operation in the deposition process. The first gas exhaust system is prohibited from performing exhausting operation in the purging process. The second gas exhaust system is connected to an upper portion of the reaction chamber. The first gas exhaust system includes a second pump outside the reaction chamber. The second gas exhaust system is prohibited from performing exhausting operation in the deposition process. The second gas exhaust system performs exhausting operation in the purging process.

In still another embodiment, a method of atomic layer deposition may include, but is not limited to, the following processes. A first gas is supplied above a plurality of semiconductor substrate in a reaction chamber while the first gas is exhausted in the reaction chamber by a first gas exhaust system in a first deposition process. The first gas contains a first material. A purge gas is supplied into the reaction chamber while the first gas and the purge gas are exhausted in the reaction chamber by a second gas exhaust system in a purging process. The purging process follows the first deposition process. A reaction gas is supplied above the plurality of semiconductor substrates while the reaction gas is exhausted by the first gas exhaust system in a second deposition process. The reaction gas is to be reacted with the first material. The second deposition process follows the purging process. A set of supplying the first gas, supplying the purge gas, and supplying a reaction gas is repeated to form a number of atomic layer thin films on the plurality of semiconductor substrates.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a longitudinal cross sectional elevation view briefly illustrating an ALD apparatus of one embodiment of the present invention;

FIG. 2 is a plan view showing FIG. 1 in the direction indicated by an arrow A;

FIG. 3 is a timing chart of supplying each gases in a film formation process; and

FIG. 4 is a figure showing a measurement result of a zirconium oxide film formed in accordance with examples of the present invention.

### DETAILED DESCRIPTION OF THE PREFERRED EMBODIMENTS

Before describing the present invention, the related art will be explained in detail, in order to facilitate the understanding of the present invention.

In the conventional ALD film-forming apparatus in which the shielding plate is disposed in the reaction chamber, it is possible to reduce an interval between the wafer and the shielding plate. Since the gas flows so as to intensively surround each wafer from each supply holes of the gas supply pipe toward each exhaust holes without practically flowing to the outside of the shielding plate, the gas can be uniformly supplied to the wafer surface. However, since the shielding plate is provided, flow conductance (the flow of a gas) is considerably reduced, and purge using an inert gas can be insufficient. When the purge is insufficient, a reaction product caused by the remaining source gas will be deposited on the wafer. Thus, it is difficult to uniformly form a single atomic layer. On the other hand, when the purge is sufficiently performed, it takes a long period of time due to low conductance. As such, the productivity is considerably reduced.

Further, according to the conventional ALD film-forming apparatus for which the shielding plate is not provided, the purge can be rapidly performed compared to the ALD film-forming apparatus for which the shielding plate is provided. However, it can be hard that the film is uniformly formed since a distance between the wafer and an inner wall of the reaction chamber is greater than an interval between the adjacent wafers. Thus, the source gas supplied from the gas supply pipe is likely to flow between the wafer and the reaction chamber. For this reason, an amount of the source gas supplied to the wafer surface becomes non-uniform. In addition, it is difficult to uniformly form a film on the wafer surface. Further, the film with an uneven thickness tends to be formed because of the distance from each wafer to the gas exhaust port.

Further, even in the ALD film-forming apparatus for which the shielding plate is not provided, it is necessary to perform a purging process for a long period of time in order to compensate for the shortage of exhausting capacity in the case where the priority is focused on the uniformity of the formed film. This is because it is difficult to increase the exhaust port to some extent or more in order to prevent turbulence of the source gas in the vicinity of the exhaust port and in order to improve the uniformity of the film. For example, as in the related art, even when a slit-shaped exhaust port is provided, a width of the slit can be set only to a certain size or less. Thus, the exhausting capacity in the purging process becomes insufficient. Further, even in the case of an exhaust port having another shape, it is also difficult to make the exhaust port large. Thus, it is difficult to have sufficient exhausting capacity.

As described above, the conventional ALD film-forming apparatus includes one exhaust line system used in both the step of supplying the purge gas and the step of supplying the source gas. Therefore, conditions for operating the conventional ALD film-forming apparatus should be determined depending on either of the uniformity of the formed film or the reduction of the time required for the film formation which reads an improvement of the productivity. Therefore, it is difficult to achieve both of the uniformity of the formed film and the reduction of the time required for the film formation.

Embodiments of the invention will be now described herein with reference to illustrative embodiments. Those skilled in the art will recognize that many alternative embodiments can be accomplished using the teaching of the embodiments of the present invention and that the invention is not limited to the embodiments illustrated for explanatory purpose.

In one embodiment, an atomic layer deposition apparatus may include, but is not limited to, a reaction chamber, a wafer boat in the reaction chamber, a gas supply system connected to the reaction chamber, a first gas exhaust system connected to the reaction chamber, and a second gas exhaust system connected to the reaction chamber. The gas supply system supplies at least a material gas into the reaction chamber in a deposition process. The gas supply system supplies a purge gas into the reaction chamber in a purging process. The first gas exhaust system performs exhausting operation in the deposition process. The first gas exhaust system is prohibited from performing exhausting operation in the purging process. The second gas exhaust system is prohibited from performing exhausting operation in the deposition process. The second gas exhaust system performs exhausting operation in the purging process.

In some cases, the atomic layer deposition apparatus may include, but is not limited to, the gas supply system supplying, as the material gas, a reaction gas and a first gas alternatively. The first gas contains a first material to be reacted with the reaction gas in the deposition process.

In some cases, the atomic layer deposition apparatus may include, but is not limited to, the gas supply system supplying the first gas in a first deposition process. The first gas exhaust system performs exhausting operation in the first deposition process. The gas supply system supplies the purge gas in the purging process following to the first deposition process. The second gas exhaust system performs exhausting operation in the purging process. The gas supply system supplies the reaction gas in a second deposition process following to the purging process. The first gas exhaust system performs exhausting operation in the second deposition process.

In some cases, the atomic layer deposition apparatus may include, but is not limited to, the second gas exhaust system having a connection portion connected to an upper portion of the reaction chamber. The connection portion is positioned above the first gas exhaust system.

In some cases, the atomic layer deposition apparatus may include, but is not limited to, the gas supply system including a feeder outside the reaction chamber and a gas supply nozzle in the reaction chamber. The first gas exhaust system includes a first exhauster outside the reaction chamber and a gas suction nozzle in the reaction chamber. The gas supply nozzle and the gas suction nozzle are opposed to each other with reference to the wafer boat.

In some cases, the atomic layer deposition apparatus may include, but is not limited to, the second gas exhaust system including a second exhauster outside the reaction chamber. The first exhauster includes a first pump. The second exhauster includes a second pump.

In some cases, the atomic layer deposition apparatus may include, but is not limited to, the second gas exhaust system including a second exhauster outside the reaction chamber. The first exhauster and the second exhauster include a common pump.

In some cases, the atomic layer deposition apparatus may include, but is not limited to, the gas supply nozzle positioned between an inner wall of the reaction chamber and the wafer boat.

In some cases, the atomic layer deposition apparatus may include, but is not limited to, the first exhauster including a first exhaust pump and a first exhaust valve between the first exhaust pump and the reaction chamber, the first exhaust valve is open in the deposition process, and the first exhaust valve is closed in the purging process.

In some cases, the atomic layer deposition apparatus may include, but is not limited to, the second gas exhaust system including a second exhauster outside the reaction chamber and a first exhaust pipe connected to the reaction chamber. The first exhaust pipe is lager in diameter than the gas suction nozzle.

In some cases, the atomic layer deposition apparatus may include, but is not limited to, the second exhauster including a second exhaust pump and a second exhaust valve between the second exhaust pump and the reaction chamber. The second exhaust valve is open in the purging process. The second exhaust valve is closed in the deposition process.

In some cases, the atomic layer deposition apparatus may include, but is not limited to, the wafer boat having a plurality of holders to hold a plurality of wafers separately from each other. The plurality of wafers overlap with each other in plan view.

In some cases, the atomic layer deposition apparatus may include, but is not limited to, the gas supply nozzle having a plurality of supply holes. The number of the plurality of supply holes is at least the same as the number of the plurality of holders.

In some cases, the atomic layer deposition apparatus may include, but is not limited to, the gas supply system configured to eject the material gas from the plurality of gas supply holes in a direction approximately parallel to upper surfaces of the wafers.

In some cases, the atomic layer deposition apparatus may include, but is not limited to, the gas suction nozzle including a plurality of gas exhaust holes. The number of the plurality of gas exhaust holes is the same as the number of the plurality of holders.

In some cases, the atomic layer deposition apparatus may include, but is not limited to, the first gas exhaust system configured to suction the material gas from the gas exhaust holes in a direction approximately parallel to upper surfaces of the wafers.

In some cases, the atomic layer deposition apparatus may include, but is not limited to, the following feature. An amount of exhausted gas per unit time of the second exhaust system is more than that of the first exhaust system.

In some cases, the atomic layer deposition apparatus may include, but is not limited to, a rotating mechanism supporting the wafer boat. The rotating mechanism is disposed in the reaction chamber.

In another embodiment, an atomic layer deposition apparatus may include, but is not limited to, a reaction chamber, a gas supply system, a first gas exhaust system, and a second gas exhaust system. The gas supply system is connected to the reaction chamber. The gas supply system supplies a first gas into the reaction chamber in a first deposition process. The gas supply system supplies a purge gas into the reaction chamber in a purging process following to the first deposition process. The gas supply system supplies a reaction gas into the reaction chamber in a second deposition process following to the purging process. The first gas contains a first material to be reacted with the reaction gas. The first gas exhaust system is connected to the reaction chamber. The first gas exhaust system performing exhausting operations in the first deposition process and a second deposition process respectively. The second deposition process follows to the purging process. The first gas exhaust system is prohibited from performing exhausting operation in the purging process. The second gas exhaust system is connected to the reaction chamber. The second gas exhaust system is prohibited from performing exhausting operation in the first and second deposition processes. The second gas exhaust system performs exhausting operation in the purging process.

In still another embodiment, an atomic layer deposition apparatus may include, but is not limited to, a reaction chamber, a wafer boat, a rotating mechanism, a gas supply system, a first gas exhaust system, and a second gas exhaust system. The wafer boat is in the reaction chamber. The rotating mechanism supports the wafer boat. The rotating mechanism is disposed in the reaction chamber. The gas supply system is connected to the reaction chamber. The gas supply system includes a gas supply nozzle in the reaction chamber. The gas supply system supplies, as a material gas, a reaction gas and a first gas alternatively into the reaction chamber in a deposition process. The first gas contains a first material to be reacted with the reaction gas in the deposition process. The gas supply system supplies a purge gas into the reaction chamber in a purging process. The first gas exhaust system is connected to the reaction chamber. The first gas exhaust system includes a first gas suction nozzle in the reaction chamber. The first gas exhaust system includes a first pump outside the reaction chamber. The first gas suction nozzle is opposite to the gas supply nozzle with reference to the wafer boat. The first gas exhaust system performs exhausting operation in the deposition process. The first gas exhaust system is prohibited from performing exhausting operation in the purging process. The second gas exhaust system is connected to an upper portion of the reaction chamber. The first gas exhaust system includes a second pump outside the reaction chamber. The second gas exhaust system is prohibited from performing exhausting operation in the deposition process. The second gas exhaust system performs exhausting operation in the purging process.

In still another embodiment, a method of atomic layer deposition may include, but is not limited to, the following processes. A first gas is supplied into a reaction chamber while the first gas is exhausted in the reaction chamber by a first gas exhaust system in a first deposition process. The first gas contains a first material. A purge gas is supplied into the reaction chamber while the first gas and the purge gas are exhausted in the reaction chamber by a second gas exhaust system in a purging process. The purging process follows the first deposition process. A reaction gas is supplied into the reaction chamber while the reaction gas is exhausted by the first gas exhaust system in a second deposition process. The reaction gas is to be reacted with the first material. The second deposition process follows the purging process.

In some cases, the method may further include, but is not limited to, the following processes. The second gas exhaust system is prohibited from exhausting the first gas from the reaction chamber while supplying the first gas. The first gas exhaust system is prohibited from exhausting the first gas and the purge gas from the reaction chamber while supplying the purge gas. The second gas exhaust system is prohibited from exhausting the reaction gas from the reaction chamber while supplying the reaction gas.

In some cases, the method may include, but is not limited to, repeating a set of supplying the first gas, supplying the purge gas, and supplying a reaction gas.

In still another embodiment, a method of atomic layer deposition may include, but is not limited to, the following processes. A first gas is supplied above a plurality of semiconductor substrate in a reaction chamber while the first gas is exhausted in the reaction chamber by a first gas exhaust system in a first deposition process. The first gas contains a first material. A purge gas is supplied into the reaction chamber while the first gas and the purge gas are exhausted in the reaction chamber by a second gas exhaust system in a purging process. The purging process follows the first deposition process. A reaction gas is supplied above the plurality of semiconductor substrates while the reaction gas is exhausted by the first gas exhaust system in a second deposition process. The reaction gas is to be reacted with the first material. The second deposition process follows the purging process. A set of supplying the first gas, supplying the purge gas, and supplying a reaction gas is repeated to form a number of atomic layer thin films on the plurality of semiconductor substrates.

In some cases, the method may further include, but is not limited to, the following processes. The second gas exhaust system is prohibited from exhausting the first gas from the reaction chamber while supplying the first gas. The first gas exhaust system is prohibited from exhausting the first gas and the purge gas from the reaction chamber while supplying the purge gas. The second gas exhaust system is prohibited from exhausting the reaction gas from the reaction chamber while supplying the reaction gas.

Hereinafter, a semiconductor device according to an embodiment of the invention will be described in detail with reference to the drawings. In the embodiment, an atomic layer deposition (ALD) film-forming apparatus will be described. In the drawings used for the following description, to easily understand characteristics, there is a case where characteristic parts are enlarged and shown for convenience' sake, and ratios of constituent elements may not be the same as in reality. Materials, sizes, and the like exemplified in the following description are just examples. The invention is not limited thereto and may be appropriately modified within a scope which does not deviate from the concept of the invention.

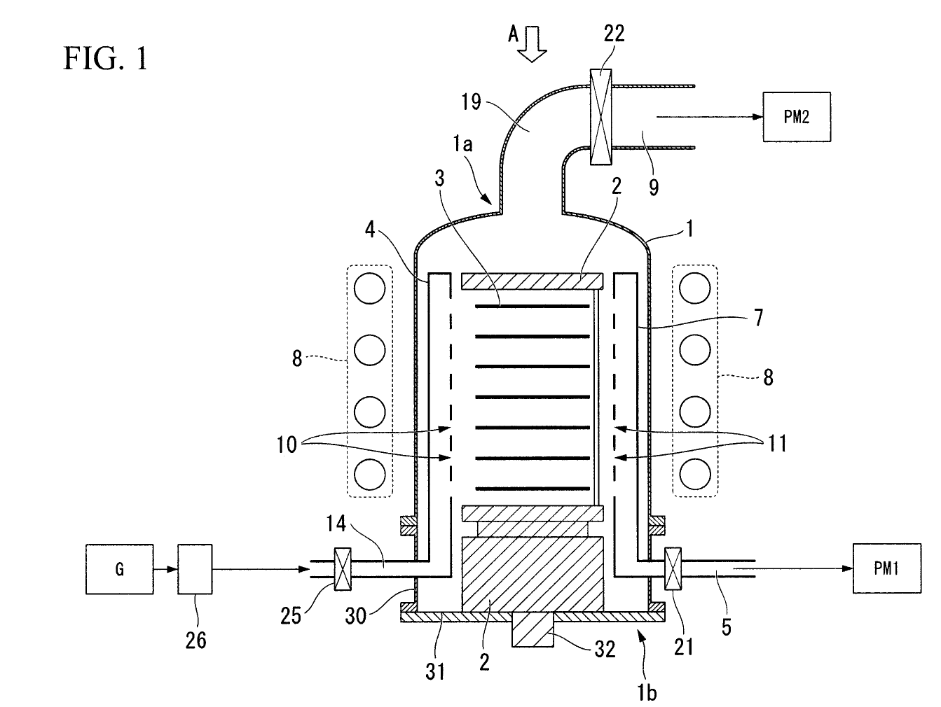

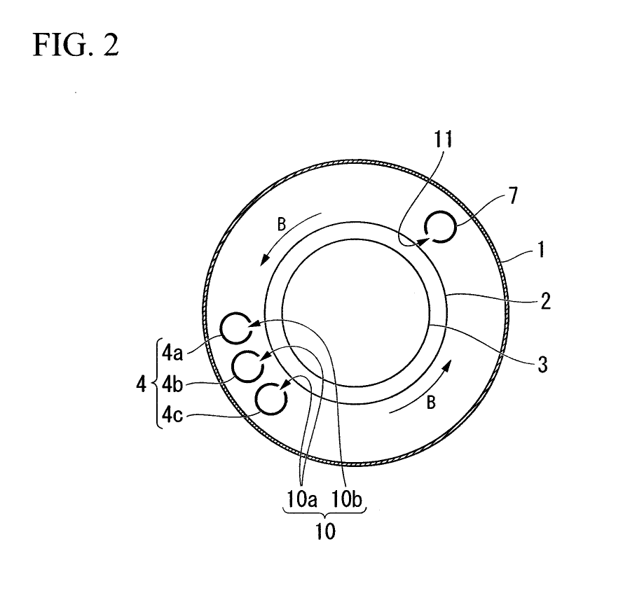

An atomic layer deposition (ALD) film-forming apparatus 100 of the present invention will be described with reference to FIGS. 1 and 2.

FIG. 1 is a longitudinal cross-sectional view schematically illustrating an ALD film-forming apparatus 100 according to the present embodiment. The ALD film-forming apparatus 100 of the present embodiment is a batch-type film-forming apparatus for depositing an insulating film, and the like. The ALD film-forming apparatus 100 can simultaneously process a plurality of wafers 3. The ALD film-forming apparatus 100 may include, but is not limited to, a reaction chamber 1, a gas supply pipe 4, a first exhaust pipe 7, a second exhaust pipe 19, and a heater 8. The reaction chamber 1 has a hollow cylindrical shape. The gas supply pipe 4, the first exhaust pipe 7, and the second exhaust pipe 19 are installed inside the reaction chamber 1. The heater 8 is installed outside the reaction chamber 1. Hereinafter, these components will be described in detail.

### Reaction Chamber 1

The reaction chamber 1 is made of, for instance, quartz. The reaction chamber 1 has a vertical hollow cylindrical structure. The vertical hollow cylindrical structure has a first tapered upper portion 1a which decreases the diameter as it becomes close to the top. A second end (a lower end) 1b of the vertical hollow cylindrical structure is engaged with a hollow cylindrical manifold 30 made of, for instance, stainless steel. Further, an opening (not shown) is provided on the second end 1b side (a lower side) of the manifold 30. To seal the opening, a cap part 31 is provided. Thereby, the interior of the reaction chamber 1 is kept airtight, and its pressure can be controlled. Further, a rotating mechanism 32 is provided below the cap part 31. The rotating mechanism 32 passes through the cap part 31 and protrudes outwardly from the reaction chamber 1

### Wafer Boat 2

The wafer boat 2 is made of, for instance, quartz, and is installed on the cap part 31. The wafer boat 2 is provided with a plurality of holders. The plurality of holders may be protrusions or grooves (not shown). The wafers 3 are held by the plurality of holders separately from each other so that the wafers 3 overlap with each other in plain view. Further, the wafers 3 are disposed so as to be approximately parallel to the floor on which the ALD film-forming apparatus 100 is installed. The wafer boat 2 is allowed to be integrally moved to a predetermined position in the reaction chamber 1 by moving the cap part 31 up and down.

Further, the wafer boat 2 is supported by the rotating mechanism 32 at the center of the bottom surface thereof. The wafer boat 2 can be rotated with the interior of the reaction chamber 1 kept airtight. Thereby, the wafer boat 2 and the wafers 3 can be rotated, so that it is possible to improve film-forming uniformity.

### Gas Supply Pipe 4

The gas supply pipe 4 may include, but is not limited to, a purge gas supply pipe 4a, a first source gas supply pipe 4b, and a second source gas supply pipe 4c. The number or kind of these gas supply pipes 4 is not limited to those listed here, and thus can be appropriately changed depending on a kind of gas to be used. As such, even when three or more kinds of source gases are used, the present embodiment can be applied. The gas supply pipes 4 and the gas supply units G may be properly and independently provided in the ALD film-forming apparatus 100 depending on each necessary supply gas. Gas Supply Pipes 4 (Purge Gas Supply Pipe 4a, First Source Gas Supply Pipe 4b, and Second Source Gas Supply Pipe 4c)

As shown in FIGS. 1 and 2, the gas supply pipes 4 which are the purge gas supply pipe 4a, the first source gas supply pipe 4b, and the second source gas supply pipe 4c are each interposed between an inner wall of the reaction chamber 1 and the wafer boat 2.

FIG. 2 is a plan view showing FIG. 1 in the direction indicated by an arrow A. As shown in FIG. 2, the purge gas supply pipe 4a is, for example, installed at a position adjacent to the first source gas supply pipe 4b and the second source gas supply pipe 4c.

Further, the gas supply pipes 4 are provided with a plurality of gas supply holes 10 which are first gas supply holes 10a and second gas supply holes 10b. The first gas supply holes 10a and the second gas supply holes 10b are located at positions corresponding to the respective wafers 3. In other words, the first gas supply holes 10a and the second gas supply holes 10b are provided at approximately the same heights as the respective wafers 3. The gas supply holes 10 are provided in the respective gas supply pipes 4 at positions corresponding to the positions of the wafers 3. The number of the gas supply holes 10 is at least the same number as the number of wafers 3 that the wafer boat 2 is designed to hold. In other words, the number of the gas supply holes 10 is at least the same number as the number of the plurality of holders. These gas supply pipes 4 function as gas supply nozzles. The gas supply pipes 4 can eject the source gas or the purge gas from the gas supply holes 10 in a direction approximately parallel to the upper surfaces of the respective wafers 3. Thereby, the source gas or the purge gas is uniformly supplied to each wafer 3.

Further, a plurality of gas supply lines 14 are installed outside the reaction chamber 1. These gas supply lines 14 are connected to upstream of the respectively corresponding gas supply pipes 4.

Gas supply valves 25 are provided on the upstream of the gas supply lines 14. The gas supply valves 25 are configured to be openable and closable, and can control supply and cutoff of the gas to and from the gas supply lines 14.

Further, a gas flow controller 26 and the gas supply units G are connected to upstream ends of the gas supply lines 14. Thereby, source gases supplied from the gas supply units G are subjected to the control of their flow rates by the gas flow controller 26 and the gas supply valves 25. Then, the source gases are supplied from the gas supply holes 10 of the gas supply pipes 4 toward the respective wafers 3.

Here, as the gas supply G, a vaporizer or an ozone generator may be used. Further, the gas supply G may be configured to eject the mixture from one gas supply pipe 4 by diluting the source gas with a carrier gas (an inert gas) and mixing them.

### First Exhaust Pipe 7

As shown in FIGS. 1 and 2, the first exhaust pipe 7 and the gas supply pipes 4 are opposed to each other with reference to the wafer boat 2 (the wafers 3).

Additionally, the first exhaust pipe 7 is provided with a plurality of exhaust holes 11 that are located at positions corresponding to the respective wafers 3. In other words, the exhaust holes 11 are provided at approximately the same heights as the respective wafers 3. The number of the exhaust holes 11 is at least the same number as the number of wafers 3 that the wafer boat 2 is designed to hold. In other words, the number of the gas exhaust holes 11 is at least the same number as the number of the plurality of holders.

The first exhaust pipe 7 and the exhaust holes 11 are used when the source gas is supplied. The source gas is suctioned from the exhaust holes 11 of first exhaust pipe 7 in a direction approximately parallel to the upper surfaces of the wafers 3. Thereby, the unnecessary source gas is rapidly exhausted from the vicinity of the surface of each wafer 3 or between the wafers 3. The first exhaust pipe 7 has the exhaust holes 11 that function as exhaust ports supplying the source gas into the reaction chamber 1. Further, the first exhaust pipe 7 may be installed in plural numbers within a range where it does not impede the flow of the purge gas in a process of exhausting the purge gas in the reaction chamber 1.

Further, a first exhaust line 5 is installed outside the reaction chamber 1, and connected to a downstream of the corresponding first exhaust pipe 7.

In addition, a first exhaust valve 21 is installed on a downstream of the first exhaust line 5. The first exhaust valve 21 is configured to be openable and closable. The first exhaust valve 21 can control an amount of exhaust gas flowing through the first exhaust line 5.

A first vacuum pump PM1 is connected to the downstream end of the first exhaust line 5. Thereby, the gas in the reaction chamber 1 is suctioned through the exhaust holes 11 by the first vacuum pump PM1, and is exhausted through the first exhaust pipe 7 and the first exhaust line 5.

### Second Exhaust Pipe 19

As shown in FIG. 1, the second exhaust pipe 19 is connected to the first end la of the reaction chamber 1. The second exhaust pipe 19 is used when the purge gas is supplied. The purge gas is suctioned from the second exhaust pipe 19 in a direction that is approximately perpendicular to the upper surface of each wafer 3.

Further, the second exhaust pipe 19 employs a pipe with a larger diameter than the first exhaust pipe 7. Thereby, an amount of exhausted gas per unit time of the second exhaust pipe 19 can be made more than that of the first exhaust pipe 7. Further, a position where the second exhaust pipe 19 is installed is not limited to the first end 1a of the reaction chamber 1. The second exhaust pipe 19 may be installed on the second end 1b. In addition, the second exhaust pipe 19 may be installed at a plurality of places as well as one place.

Further, a second exhaust line 9 is connected to a downstream of the second exhaust pipe 19 via a second exhaust valve 22. The second exhaust valve 22 is configured to be openable and closable. The second exhaust valve 22 can control an amount of exhaust gas flowing through the second exhaust line 9.

Further, a second vacuum pump PM2 is connected to the downstream end of the second exhaust line 9. The purge gas in the reaction chamber 1 is drawn in from the second exhaust pipe 19 by suction of the second vacuum pump PM2. The purge gas in the reaction chamber 1 is exhausted to the outside of the reaction chamber 1 through the second exhaust pipe 19 and the second exhaust line 9. The second exhaust pipe 19 functions as an exhaust port of the purge gas in the reaction chamber 1. A single pump may be used for the first vacuum pump PM1 and the second vacuum pump PM2. Since the second exhaust pipe 19 has a larger diameter than that of the first exhaust pipe 7, an amount of exhausted gas per unit time of the second exhaust pipe 19 can be made more than that of the first exhaust pipe 7 even when the same pump is used.

Further, the second exhaust line 9 employs a pipe with a larger diameter than that of the first exhaust line 5. As such, an amount of exhausted gas per unit time of the second exhaust line 9 can be made more than that of the first exhaust line 5.

In this way, the ALD film-forming apparatus 100 of the present embodiment can exhaust the purge gas through the second exhaust line 9 and the second exhaust pipe 19. Since the second exhaust line 9 has a larger diameter than that of the first exhaust line 5 and the second exhaust pipe 19 has a larger diameter than that of the first exhaust pipe 7, an amount of exhausted purge gas per unit time can be greater than an amount of exhausted source gas.

### Heater 8

As shown in FIG. 1, the heater 8 is installed outside the reaction chamber 1. The heater 8 can set a predetermined temperature in the interior of the reaction chamber 1. Thereby, the wafers 3 can be heated to a predetermined temperature.

Here, in this embodiment, the ALD film-formation apparatus 100 includes a gas supply system. The gas supply system may include, but is not limited to, a feeder and at least a gas supply nozzle. The feeder may include, but is not limited to, the gas supply units G, the gas flow controller 26, the gas supply valves 25, and the gas supply lines 14. The feeder is provided outside the reaction chamber. The gas supply nozzle may include, but is not limited to, the gas supply pipe 4. The gas supply nozzle is provided inside the reaction chamber. The gas supply nozzle extends in the vertical direction.

The gas supply nozzle is interposed between the inside wall of the reaction chamber 1 and the wafer boat 2. The gas supply nozzle can be realized by the gas supply pipe 4 with the gas supply holes 10.

Also, the ALD film-formation apparatus 100 includes a first gas exhaust system. The first gas exhaust system may include, but is not limited to, a first exhauster outside the reaction chamber and a gas exhaust nozzle in the reaction chamber. The gas suction nozzle can be used as a gas exhaust nozzle that is used to exhaust gas in the reaction chamber. The first exhauster may include, but is not limited to, the first vacuum pump PM1, the first exhaust line 5, and the first exhaust valve 21. The gas exhaust nozzle extends in the vertical direction. The gas exhaust nozzle is interposed between the inside wall of the reaction chamber 1 and the wafer boat 2. The gas exhaust nozzle and gas supply nozzle are opposed to each other with reference to the wafer boat 2. The gas exhaust nozzle can be realized by the first exhaust pipe 7 with the exhaust holes 11. The first gas exhaust system may include a plurality of gas exhaust nozzles.

Also, the ALD film-formation apparatus 100 includes a second gas exhaust system. The second gas exhaust system may include, but is not limited to, a second exhauster and the second exhaust pipe 19. The second exhauster may include, but is not limited to, the second vacuum pump PM2, the second exhaust line 9, and the second exhaust valve 22. The second exhauster is provided outside the reaction chamber.

According to the ALD film-forming apparatus 100 of the present embodiment, the first exhaust pipe 7 having the exhaust holes 11 the gas supply pipes 4 having the gas supply holes 10 are opposed to each other with reference to the wafers 3. The gas supply holes 10 and the exhaust holes 11 are provided at positions corresponding to the respective wafers 3. As such, it is possible to control a pressure gradient on the surface of each wafer 3. Also, it is possible to cause the source gas to flow in a laminar flow. Further, it is possible to uniformly supply the source gas onto the wafers 3, and thus it is possible to improve the uniformity of the formed film.

Further, the exhaust line and the exhaust pipe of exhaust systems for the source gas and the exhaust line and the exhaust pipe of exhaust systems for the purge gas are installed independently. Thereby, when the source gas is supplied, turbulence of the source gas may not occur around the exhaust port of the second exhaust pipe 19. As such, it is possible to make the diameter of the second exhaust pipe 19 larger than the diameter of a conventional exhaust port. Thus, when purging is performed using the purge gas, the second exhaust pipe 19 with a larger diameter than the first exhaust pipe 7 can be used. Thereby, an amount of exhausted gas per unit time of the second exhaust pipe 19 can be made more than that of the first exhaust pipe 7. By virtue of this, it is possible to suppress that the source gas remains in the reaction chamber 1. Additionally, the purging is performed rapidly. Thereby, it is possible to reduce a time required for film formation, and to improve productivity.

With this structure, it is possible to achieve the improvement of the uniformity of the formed film using the ALD film-forming apparatus 100. In addition, it is possible to achieve the reduction of the time required for the film formation using the ALD film-forming apparatus 100, which leads the improvement of the productivity.

Next, a method of fabricating a semiconductor device using the ALD film-forming apparatus 100 of the present embodiment will be described with reference to FIGS. 1 through 3.

The method of fabricating the semiconductor device of the present embodiment generally includes the following processes. Process 51 includes a process of loading the wafer boat 2 holding the wafers 3 into the reaction chamber 1 and keeping the reaction chamber 1 airtight, a process of supplying a first source gas into the reaction chamber 1. Process S2 includes a process of purging the first source gas. Process S3 includes a process of supplying a second source gas into the reaction chamber 1. Process S4 includes a process of purging the second source gas. Hereinafter, these processes will be described in detail.

### Process of Keeping Reaction Chamber 1 Airtight

First, as shown in FIG. 1, a plurality of wafers 3 (e.g. 100 wafers) are held on the wafer boat 2. Then, the wafer boat 2 is loaded into the reaction chamber 1. The second end 1b of the reaction chamber 1 is closed by the cap part 31. Thereby, the reaction chamber 1 is kept airtight.

Afterwards, as shown in FIG. 2, in the present embodiment, the wafer boat 2 is rotated in a direction indicated by an arrow B of FIG. 2 by the rotating mechanism 3 until a film-forming process is completed. At this time, a rotational speed of the wafer boat 2 is set to be, for instance, 1 rpm. In this manner, by rotating the wafer boat 2 during the film-forming process, the source gas can be uniformly adsorbed onto the surface of each wafer 3. Also, a temperature of the surface of each wafer 3 can be kept constant.

In FIGS. 1 and 2, the arrangement of the gas supply pipes 4, which are the purge gas supply pipe 4a, the first source gas supply pipe 4b, and the second source gas supply pipe 4c, and the first exhaust pipe 7 is shown. The number or kind of these gas supply pipes 4 is not limited to those listed here, and thus may be appropriately changed depending on a kind of gas to be used. The gas supply pipes 4 and the gas supply units G, which are independently provided for each necessary supply gas, may be properly provided in the ALD film-forming apparatus 100. Here, for example, two kinds of gases may be used as the source gas. As shown in FIG. 2, the ALD film-forming apparatus 100 of the present embodiment includes two gas supply pipes 4 for the source gas, namely, the first source gas supply pipe 4b and the second source gas supply pipe 4c. Further, the purge gas supply pipe 4a for supplying the purge gas is installed at a position adjacent to the first source gas supply pipe 4b or the second source gas supply pipe 4c for the source gas.

As shown here, the first exhaust pipe 7 and the gas supply pipes 4 are opposed to each other with reference to the wafers 3. Further, the gas supply pipes 4 are provided with a plurality of gas supply holes 10 which are located at approximately the same heights as the respective wafers 3, respectively. The gas supply holes 10 correspond to first gas supply holes 10a and second gas supply holes 10b. Also, the first exhaust pipe 7 is provided with a plurality of exhaust holes 11 which are located at approximately the same heights as the respective wafers 3. The first gas supply pipes 4a and the second gas supply pipes 4b function as gas supply nozzles. The first gas supply pipes 4a and the second gas supply pipes 4b can eject the source gas or the purge gas in a direction approximately parallel to the upper surfaces of the respective wafers 3.

Here, for example, a method for forming a zirconium oxide (ZrO₂) film will be described in detail. After the film-forming process is initiated, an amount of exhaust gas is regulated such that an atmospheric pressure in the reaction chamber 1 is kept, for instance to a range from 130 Pa to 140 Pa by using one of the first exhaust line 5 and the second exhaust line 9. However, in the case of the process of purging the first source gas (process S2) and the process of purging the second source gas (process S4), both of which will be described below, the atmospheric pressure in the reaction chamber 1 may be temporarily changed. This is because, to perform rapid purge, it is necessary to rapidly raise the pressure. Here, for example, the atmospheric pressure in the reaction chamber 1 is maintained through the first exhaust line 5.

Further, in this case, an atmosphere and each wafer 3 in the reaction chamber 1 are uniformly heated to approximately 200° C. by the heater 8. In the film-forming process including the following processes, the temperature of the interior of the reaction chamber 1 is adjusted by the heater 8 so as to be set to about 200° C.

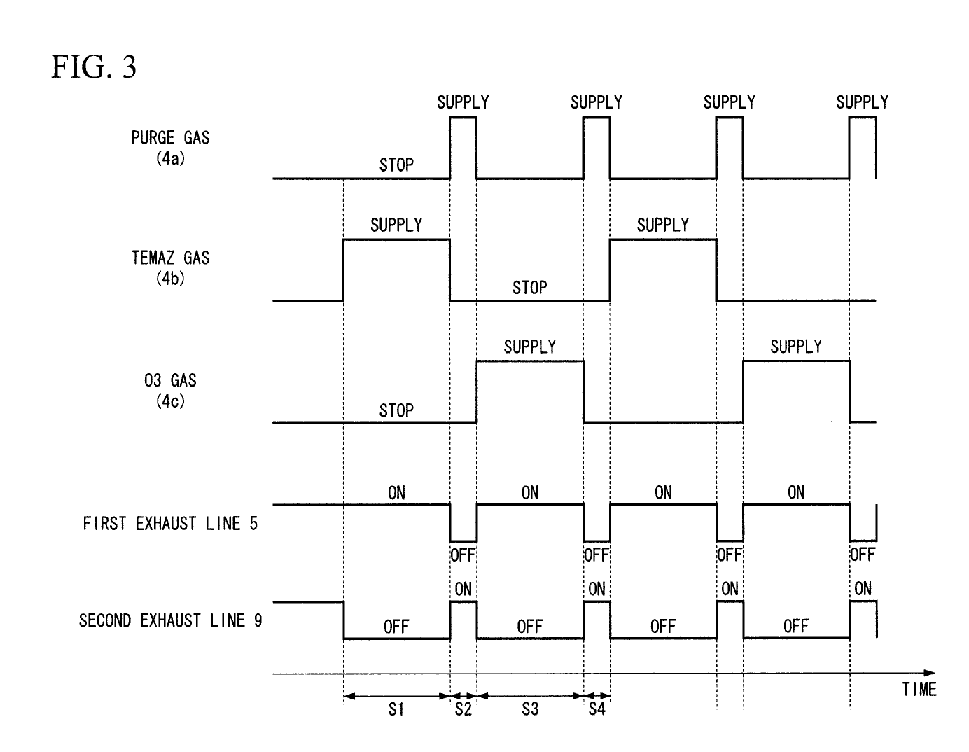

FIG. 3 is a timing chart showing a supply state of each gas when a zirconium oxide film is formed. To form the zirconium oxide film, the wafer 3 adsorbs zirconium and then the zirconium is oxidized.

Here, for example, tetrakis(ethylmethylamino)zirconium (TEMAZ) gas may be used as the first source gas, and ozone (O₃) gas may be used as the second source gas. The kinds of these gases are examples, and thus other gases may also be used. Further, as the purge gas, an inert gas such as nitrogen (N₂) or argon (Ar) may be used.

### Process S1: Process of Supplying First Source Gas Into Reaction Chamber 1

First, TEMAZ gas from the gas supply G and the gas flow controller 26 via the gas supply line 14 is supplied from the first gas supply holes 10a of the first source gas supply pipe 4b into the reaction chamber 1, for instance, for 100 seconds. At this time, the TEMAZ gas may be supplied into the reaction chamber 1 with an inert gas such as N₂ or Ar as a carrier gas diluted and mixed therewith. In this case, the source gas may be diluted and mixed with the carrier gas (an inert gas) in the gas supply G, and then may be ejected from the first source gas supply pipe 4b.

At this time, each gas flow rate, for example, may be set to 40 sccm for the TEMAZ gas and to 10 standard liters per minute (SLM) for the carrier gas. That is, it is shown in FIG. 3 that, when the TEMAZ gas is supplied, the TEMAZ gas diluted with the carrier gas is supplied into the reaction chamber 1.

Further, a flow rate of the source gas supplied from the gas supply G can be regulated by the gas flow controller 26 and the gas supply valve 25. Thereby, an amount of the gas supplied to each wafer 3 can be regulated.

Here, since the first gas supply holes 10a are located at approximately the same heights as the respective wafers 3, the first source gas (the TEMAZ gas) ejected from the first gas supply holes 10a is supplied in the directions approximately parallel to the upper surfaces of the respective wafers 3. At this time, since the wafer boat 2 is rotated by the rotating mechanism 32, the TEMAZ gas is uniformly supplied to the surface of each wafer 3.

At this time, as shown in FIG. 3, the TEMAZ gas is supplied from the first source gas supply pipe 4b into the reaction chamber 1 while the TEMAZ gas is suctioned from the first vacuum pump PM1. Thereby, the TEMAZ gas in the reaction chamber 1 is suctioned from the exhaust holes 11 via the first exhaust line 5 and the first exhaust pipe 7. At this time, an amount of suctioned gas may be regulated by opening or closing the first exhaust valve 21 installed on a downstream of the first exhaust line 5. Thereby, the TEMAZ gas is exhausted out of the reaction chamber 1 via the first exhaust pipe 7 and the first exhaust line 5.

The exhaust holes 11 are located at approximately the same heights as the respective wafers 3, and thus the TEMAZ gas ejected from the first gas supply holes 10a flows toward the exhaust holes 11 without disturbance of its flow.

Further, at this time, the second exhaust valve 22 is in a closed state, and the exhaust through the second exhaust line 9 is stopped. That is, while the TEMAZ gas is being supplied from the first source gas supply pipe 4b, the TEMAZ gas is exhausted only via the first exhaust pipe 7. At this time, the purge gas supply pipe 4a and the second source gas supply pipe 4c are maintained in the state where the respective gas supply valves 25 are closed.

At this time, the TEMAZ gas diluted with a large volume of carrier gas is supplied into the reaction chamber 1, so that the pressure around the first gas supply holes 10a is raised. As a result, conductance is increased in a direction directed from the first gas supply holes 10a toward the center of the wafers 3.

On the other hand, the second exhaust line 9 is in a closed state, and only the exhaust via the first exhaust pipe 7 is performed, so that the pressure around the exhaust holes 11 is reduced. Thereby, the source gas flows from the first gas supply holes 10a toward the exhaust holes 11 of the first exhaust pipe 7 without disturbance of its flow. At this time, since the wafers 3 are rotated along with the wafer boat 2, the TEMAZ gas can be uniformly supplied and adsorbed to the entire surface of each wafer 3.

### Process S2: Process of Purging First Source Gas

Next, the TEMAZ gas remaining in the reaction chamber 1 is purged. In the present embodiment, nitrogen or argon is used as an inert gas (a purge gas). First, the purge gas is supplied from the purge gas supply pipe 4a into the reaction chamber 1 at a flow rate of 20 SLM for 20 seconds.

Here, since the second gas supply holes 10b of the purge gas supply pipe 4a are located at approximately the same heights as the respective wafers 3, the purge gas ejected from the second gas supply holes 10b is supplied in a direction approximately parallel to the upper surfaces of the respective wafers 3. At this time, since the wafer boat 2 is rotated by the rotating mechanism 32, the purge gas is uniformly supplied to the surface of each wafer 3.

Further, while the purge gas is being introduced, the second exhaust valve 22 is opened, and thus the purge gas is suctioned from the second vacuum pump PM2. Thereby, the first source gas and the purge gas in the reaction chamber 1 are suctioned from the second vacuum pump PM2, and are exhausted out of the reaction chamber 1 via the second exhaust pipe 19 and the second exhaust line 9. Since the second exhaust pipe 19 has a larger diameter than the first exhaust pipe 7, an amount of exhausted gas per unit time of the second exhaust pipe 19 can be made more than that of the first exhaust pipe 7.

At this time, the first exhaust valve 21 is closed, and the exhaust via the first exhaust pipe 7 and the first exhaust line 5 is stopped.

A single pump may be used for the first vacuum pump PM1 and the second vacuum pump PM2. While the purge gas is being supplied from the purge gas supply pipe 4a, the first source gas and the purge gas in the reaction chamber 1 are exhausted via only the second exhaust pipe 19 and the second exhaust line 9. Further, the gas supply valves 25 of the first source gas supply pipe 4b and the second source gas supply pipe 4c are maintained to be closed. Further, the first exhaust valve 21 of the first exhaust line 5 is also maintained to be closed.

In this manner, a large volume of purge gas is uniformly supplied to the surface of each wafer 3, while the source gas and the purge gas in the reaction chamber 1 are exhausted via the second exhaust pipe 19 and the second exhaust line 9 having a large diameter. Namely, the purge gas can be rapidly spread onto the surface of each wafer 3, and the source gas in the reaction chamber 1 can be exhausted. Thus, it is possible to purge the reaction chamber 1 within a short time.

### Process S3: Process of Supplying Second Source Gas Into Reaction Chamber 1

Subsequently, the second source gas (O₃ gas) is supplied from the first gas supply holes 10a of the second source gas supply pipe 4c into the reaction chamber 1 at a flow rate of 20 SLM for 100 seconds. Here, a concentration of the O₃ gas is set to, for instance, 250 g/m³.

At this time, the O₃ gas is supplied from the second source gas supply pipe 4c into the reaction chamber 1 while the O₃ gas in the reaction chamber 1 is exhausted via the first exhaust pipe 7 and the first exhaust line 5. At this time, the second exhaust valve 22 is closed, and the exhaust via the second exhaust line 9 is stopped. That is, while the O₃ gas is being supplied from the second source gas supply pipe 4c, the O₃ gas in the reaction chamber 1 is exhausted via only the first exhaust pipe 7. Further, the gas supply valves 25 of the purge gas supply pipe 4a and the first source gas supply pipe 4b are maintained to be closed.

Here, the first gas supply holes 10a of the second source gas supply pipe 4c are located at approximately the same heights as the respective wafers 3. Thus, the O₃ gas ejected from the first gas supply holes 10a is supplied in a direction approximately parallel to the upper surfaces of the respective wafers 3.

At this time, a large volume of O₃ gas is supplied into the reaction chamber 1, so that the pressure around the first gas supply holes 10a is raised. As a result, conductance is increased in a direction directed from the first gas supply holes 10a toward the center of the wafers 3.

Here, the second exhaust line 9 is closed, and the O₃ gas is exhausted via only the first exhaust pipe 7. Thereby, the O₃ gas flows from the first gas supply holes 10a toward the exhaust holes 11 of the first exhaust pipe 7 without disturbance of its flow. At this time, since the wafers 3 are rotated along with the wafer boat 2, the O₃ gas can be uniformly supplied to the entire surface of each wafer 3, and oxidizes the surfaces of the wafers.

In this manner, the ZrO₂ film is formed in an atomic layer level.

### Process S4: Process of Purging Second Source Gas

Next, the O₃ gas remaining in the reaction chamber 1 is purged. First, the purge gas is supplied from the purge gas supply pipe 4a into the reaction chamber 1, for instance, at a flow rate of 20 SLM for 20 seconds.

Here, the second gas supply holes 10b of the purge gas supply pipe 4a are located at approximately the same heights as the respective wafers 3. Thus, the purge gas ejected from the second gas supply holes 10b is supplied in a direction approximately parallel to the upper surfaces of the respective wafers 3. Further, while the purge gas is being introduced, the second exhaust valve 22 is opened, and thus the purge gas is suctioned from the second vacuum pump PM2. Thereby, the second source gas and the purge gas in the reaction chamber 1 are suctioned from the second exhaust pipe 19, and are exhausted out of the reaction chamber 1 via the second exhaust pipe 19 and the second exhaust line 9. Since the second exhaust pipe 19 has a larger diameter than the first exhaust pipe 7, an amount of exhausted gas per unit time of the second exhaust pipe 19 can be made more than that of the first exhaust pipe 7.

At this time, the first exhaust valve 21 is closed, and the exhaust via the first exhaust pipe 7 and the first exhaust line 5 is stopped.

That is, while the purge gas is being supplied from the purge gas supply pipe 4a, the second source gas and the purge gas in the reaction chamber 1 are exhausted via only the second exhaust pipe 19 and the second exhaust line 9. Further, the gas supply valves 25 of the first source gas supply pipe 4b and the second source gas supply pipe 4c are maintained to be closed. Further, the first exhaust valve 21 of the first exhaust line 5 is also maintained to be closed.

Afterwards, the process of supplying the first source gas into the reaction chamber 1 (process S1), the process of purging the first source gas (process S2), the process of supplying the second source gas into the reaction chamber 1 (process S3), and the process of purging the second source gas (process S4) are sequentially repeated, so that the zirconium oxide film having a predetermined thickness is formed.

In the present embodiment, the film forming method using two kinds of source gases has been described. However, the present invention can also be applied to the case in which three or more kinds of source gases are used. In this case, the source gas and the purge gas may be supplied according to a kind of necessary gas. At this time, the ALD film-forming apparatus 100 may be provided with the gas supply pipes 4 and the gas supply units G which are independent of each other are installed according to a kind of necessary gas.

According to the semiconductor device fabricating method using the ALD film-forming apparatus 100 of the present embodiment (a method of forming a thin film by an ALD method using a batch-type processing apparatus), the following processes are performed in the process of supplying the source gas. The source gas can be supplied from the gas supply pipe 4 (the gas supply holes 10) in a direction approximately parallel to the upper surfaces of the respective wafers 3 while the source gas can be exhausted from the first exhaust pipe 7 (the exhaust holes 11) that is located opposite to the gas supply pipe 4 (the gas supply holes 10) with the wafers 3 interposed therebetween. As such, it is possible to control a pressure gradient on the surface of each wafer 3. Also, it is possible to uniformly supply the source gas onto the wafers 3 and to cause the source gas to flow in a laminar flow. Thereby, it is possible to improve the uniformity of the formed film.

Further, the exhaust lines and the exhaust pipes of two exhaust systems for the source gas and the purge gas are installed. When the source gas is supplied, the source gas is not exhausted via the second exhaust pipe 19 which is used for the purging process. Therefore, no turbulence of the source gas occurs around the exhaust port of the second exhaust pipe 19. As such, it is possible to increase the diameter of the second exhaust pipe 19. Accordingly, in the purging process using the inert gas (a purge gas), the purge gas can be exhausted from the second exhaust pipe 19 and the second exhaust line 9, each of which has a larger diameter than the first exhaust pipe 7 or a conventional exhaust port. As such, it is possible to suppress that the source gas remains in the reaction chamber 1, and to perform the purging rapidly. Thereby, it is possible to reduce a time required for film formation, and to improve productivity.

As described above, in the present embodiment, the film-forming process is performed using different exhaust lines in the source gas supplying process and the purging process, respectively. Thereby, it is possible to achieve the improvement of the uniformity of the formed film and the reduction of the time required for the film formation (the improvement of the productivity).

### EXAMPLES

As examples, a method of forming a zirconium oxide film (a method of fabricating a semiconductor device) using the ALD film-forming apparatus 100 of the present embodiment was made.

In the examples, as a source gas, two kinds of gases, TEMAZ gas and O₃ gas, were used. To this end, as shown in FIGS. 1 and 2, an apparatus equipped with two source gas supply pipes 4 (the first source gas supply pipe 4b and the second source gas supply pipe 4c) and the purge gas supply pipe 4a for supplying a purge gas was used as the ALD film-forming apparatus 100.

First, a hundred wafers of a 300 mm diameter were held on the wafer boat 2. Then, the wafer boat 2 was loaded into the reaction chamber 1, and the second end 1b of the reaction chamber 1 was closed by the cap part 31. Thereby, the reaction chamber 1 was kept airtight. This state is shown in FIG. 1.

Next, the wafer boat 2 was turned around (rotated) at a rotational speed of 1 RPM in a direction indicated by an arrow B of FIG. 2 by the rotating mechanism 3. An atmosphere in the reaction chamber 1 and each wafer 3 were almost uniformly heated so as to be set to about 200° C. by the heater 8.

First, TEMAZ gas was supplied from the first source gas supply pipe 4b into the reaction chamber 1 for a hundred seconds. At this time, the TEMAZ gas was supplied into the reaction chamber 1 with N₂ as a carrier gas diluted and mixed therewith. Each gas flow rate was set to 40 sccm for the TEMAZ gas and to 10 SLM for the carrier gas.

At this time, as shown in process S1 of FIG. 3, the TEMAZ gas was supplied from the first source gas supply pipe 4b into the reaction chamber 1 while the TEMAZ gas in the reaction chamber 1 was exhausted through the first exhaust pipe 7 and the first exhaust line 5. Here, an amount of exhausted gas exhausted from the first exhaust line 5 was regulated so that an atmospheric pressure in the reaction chamber 1 was set to a range from 130 Pa to 140 Pa. The atmosphere in the reaction chamber 1 and the temperature of each wafer 3 are maintained at about 200° C.

As shown in process S2, the TEMAZ gas remaining in the reaction chamber 1 was purged by supplying nitrogen (a purge gas) into the reaction chamber 1. First, the nitrogen gas was supplied from the purge gas supply pipe 4a into the reaction chamber 1 at a flow rate of 20 SLM for 20 seconds. In the meantime, the second exhaust valve 22 was opened, and the gas in the reaction chamber 1 was exhausted only through the second exhaust pipe 19 and the second exhaust line 9. At this time, the first exhaust valve 21 was closed, and the exhaust through the first exhaust pipe 7 and the first exhaust line 5 was stopped. During this period, the atmospheric pressure and the temperature in the reaction chamber 1 were maintained at the same values as process S1.

As shown in process S3, O₃ gas having a concentration of 250 g/m³ was supplied from the second source gas supply pipe 4c into the reaction chamber 1 at a flow rate of 20 SLM for 100 seconds.

At this time, the O₃ gas was supplied from the second source gas supply pipe 4c into the reaction chamber 1 while the O₃ gas in the reaction chamber 1 was exhausted via the first exhaust pipe 7 and the first exhaust line 5. Also, the second exhaust valve 22 was closed, and the exhaust through the second exhaust line 9 was stopped. Further, the gas supply valves 25 of the purge gas supply pipe 4a and the first source gas supply pipe 4b were maintained to be closed. In addition, the atmospheric pressure and the temperature in the reaction chamber 1 were maintained at the same values as process S1.

As shown in process S4, the O₃ gas remaining in the reaction chamber 1 was purged using nitrogen (a purge gas). First, the nitrogen gas was supplied from the purge gas supply pipe 4a into the reaction chamber 1 at a flow rate of 20 SLM for 20 seconds. In the meantime, the second exhaust valve 22 was opened, and the gas in the reaction chamber 1 was exhausted only through the second exhaust pipe 19 and the second exhaust line 9. At this time, the first exhaust valve 21 was closed, and the exhaust through the first exhaust pipe 7 and the first exhaust line 5 was stopped. Further, the atmospheric pressure and the temperature in the reaction chamber 1 were maintained at the same values as process S1.

Afterwards, processes S1, S2, S3 and S4 were sequentially repeated and a number of atomic layer thin films were formed, thereby forming a zirconium oxide film having a predetermined thickness.

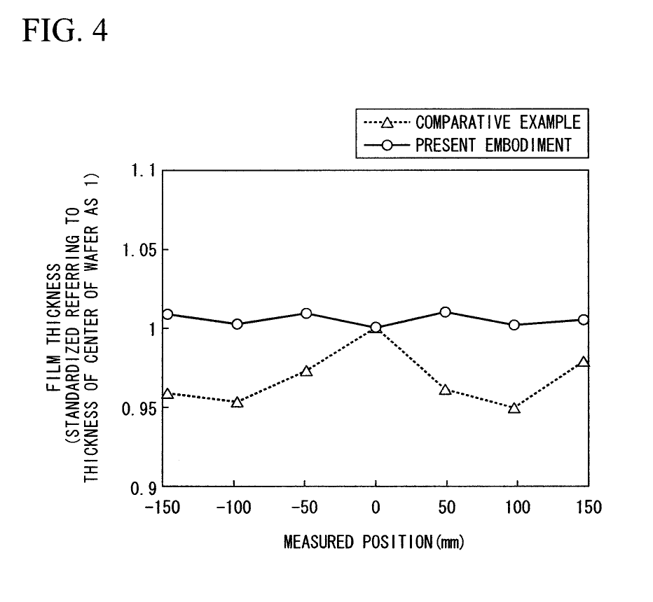

FIG. 4 shows results of measuring thicknesses of a zirconium oxide film formed according to the examples and of a zirconium oxide film formed by another method as the comparative example disclosed to be the film-forming method using the apparatus in Japanese Unexamined Patent Application, First Publication, No. JP-A-2008-053326). In the examples, the thickness of the film on the wafer 3 having a diameter of 300 mm was measured at measurement positions of seven points in a diameter direction (50 mm steps from −150 mm to +150 mm)

FIG. 4 has the horizontal axis that represents the measurement positions where the center of the wafer 3 be 0 mm and the vertical axis that represents the measured thicknesses of the zirconium oxide film where the thickness values are standardized by setting that the film thickness of the center of the wafer 3 be 1. Further, as the comparative example, results of measuring the thickness of the zirconium oxide film formed using a conventional ALD film-forming apparatus 100 having a shielding plate are shown.

As shown in the comparative example, a zirconium oxide film formed by the conventional method was thin on an outer circumferential region (+50 to +150 mm, and −50 to −150 mm) of the wafer 3 with respect to the center (0 mm) of the wafer 3. In particular, the thickness of a zirconium oxide film on the outer circumferential region of the wafer 3 is more than 5% less than a thickness of the center of the wafer 3. On the other hand, in the zirconium oxide film formed by the present invention, a thickness difference between the center of the wafer 3 and the outer circumference of the wafer 3 was 1% or less.

As shown above, according to the examples, in forming a thin film by the ALD method using the batch-type processing apparatus (the ALD film-forming apparatus 100), the zirconium oxide film that was more uniform than the conventional film was formed.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

Furthermore, the particular features, structures, or characteristics may be combined in any suitable manner in one or more embodiments.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

It is apparent that the present invention is not limited to the above embodiments, but may be modified and changed without departing from the scope and spirit of the invention.

What is claimed is:

1. An atomic layer deposition apparatus comprising:
a reaction chamber;
a wafer boat in the reaction chamber;
a gas supply system connected to the reaction chamber, the gas supply system supplying at least a material gas into the reaction chamber in a deposition process, the gas supply system supplying a purge gas into the reaction chamber in a purging process;
a first gas exhaust system connected to the reaction chamber, the first gas exhaust system performing exhausting operation in the deposition process, the first gas exhaust system being prohibited from performing exhausting operation in the purging process; and
a second gas exhaust system connected to the reaction chamber, the second gas exhaust system being prohibited from performing exhausting operation in the deposition process, the second gas exhaust system performing exhausting operation in the purging process.

2. The atomic layer deposition apparatus according to claim 1, wherein the gas supply system supplies, as the material gas, a reaction gas and a first gas alternatively, the first gas containing a first material to be reacted with the reaction gas in the deposition process.

3. The atomic layer deposition apparatus according to claim 2, wherein the gas supply system supplies the first gas in a first deposition process, the first gas exhaust system performing exhausting operation in the first deposition process,
wherein the gas supply system supplies the purge gas in the purging process following to the first deposition process, the second gas exhaust system performing exhausting operation in the purging process, and
wherein the gas supply system supplies the reaction gas in a second deposition process following to the purging process, the first gas exhaust system performing exhausting operation in the second deposition process.

4. The atomic layer deposition apparatus according to claim 3, wherein the second gas exhaust system has a connection portion connected to an upper portion of the reaction chamber,
wherein the connection portion is positioned above the first gas exhaust system.

5. The atomic layer deposition apparatus according to claim 1, wherein the gas supply system comprises a feeder outside the reaction chamber and a gas supply nozzle in the reaction chamber,
wherein the first gas exhaust system comprises a first exhauster outside the reaction chamber and a gas suction nozzle in the reaction chamber, and
wherein the gas supply nozzle and the gas suction nozzle are opposed to each other with reference to the wafer boat.

6. The atomic layer deposition apparatus according to claim 5, wherein the second gas exhaust system comprises a second exhauster outside the reaction chamber,
wherein the first exhauster comprises a first pump, and
wherein the second exhauster comprises a second pump.

7. The atomic layer deposition apparatus according to claim 5, wherein the second gas exhaust system comprises a second exhauster outside the reaction chamber, wherein the first exhauster and the second exhauster comprise a common pump.

8. The atomic layer deposition apparatus according to claim 5, wherein the gas supply nozzle is positioned between an inner wall of the reaction chamber and the wafer boat.

9. The atomic layer deposition apparatus according to claim 5, wherein the first exhauster comprises a first exhaust pump and a first exhaust valve between the first exhaust pump and the reaction chamber, the first exhaust valve is open in the deposition process, and the first exhaust valve is closed in the purging process.

10. The atomic layer deposition apparatus according to claim 5, wherein the second gas exhaust system comprises a second exhauster outside the reaction chamber and a first exhaust pipe connected to the reaction chamber,
wherein the first exhaust pipe is lager in diameter than the gas suction nozzle.

11. The atomic layer deposition apparatus according to claim 10, wherein the second gas exhaust system further comprises a second pipe connected to the reaction chamber.

12. The atomic layer deposition apparatus according to claim 5, wherein the second exhauster comprises a second exhaust pump and a second exhaust valve between the second exhaust pump and the reaction chamber, the second exhaust valve is open in the purging process, and the second exhaust valve is closed in the deposition process.

13. The atomic layer deposition apparatus according to claim 12, wherein the gas supply nozzle has a plurality of supply holes, and
wherein the number of the plurality of supply holes is at least the same as the number of the plurality of holders.

14. The atomic layer deposition apparatus according to claim 13, wherein the gas supply system is configured to supply the material gas from the plurality of gas supply holes in a direction approximately parallel to upper surfaces of the wafers.

15. The atomic layer deposition apparatus according to claim 14, wherein the gas suction nozzle comprises a plurality of gas exhaust holes, and
wherein the number of the plurality of gas exhaust holes is at least the same as the number of the plurality of holders.

16. The atomic layer deposition apparatus according to claim 15, wherein the first gas exhaust system is configured to suction at least the material gas from the gas exhaust holes in a direction approximately parallel to upper surfaces of the wafers.

17. The atomic layer deposition apparatus according to claim 1, wherein an amount of exhausted gas per unit time of the second exhaust system is more than that of the first exhaust system.

18. The atomic layer deposition apparatus according to claim 1, further comprising:
a rotating mechanism supporting the wafer boat, the rotating mechanism being disposed in the reaction chamber.

19. An atomic layer deposition apparatus comprising:
a reaction chamber;
a gas supply system connected to the reaction chamber, the gas supply system supplying a first gas into the reaction chamber in a first deposition process, the gas supply system supplying a purge gas into the reaction chamber in a purging process following to the first deposition process, the gas supply system supplying a reaction gas into the reaction chamber in a second deposition process following to the purging process, the first gas containing a first material to be reacted with the reaction gas;
a first gas exhaust system connected to the reaction chamber, the first gas exhaust system performing exhausting operations in the first deposition process and a second deposition process respectively, the second deposition process following to the purging process, the first gas exhaust system being prohibited from performing exhausting operation in the purging process; and
a second gas exhaust system connected to the reaction chamber, the second gas exhaust system being prohibited from performing exhausting operation in the first and second deposition processes, the second gas exhaust system performing exhausting operation in the purging process.

20. An atomic layer deposition apparatus comprising:
a reaction chamber;
a wafer boat in the reaction chamber;
a rotating mechanism supporting the wafer boat, the rotating mechanism being disposed in the reaction chamber;
a gas supply system connected to the reaction chamber, the gas supply system comprising a gas supply nozzle in the reaction chamber, the gas supply system supplying, as a material gas, a reaction gas and a first gas alternatively into the reaction chamber in a deposition process, the first gas containing a first material to be reacted with the reaction gas in the deposition process, the gas supply system supplying a purge gas into the reaction chamber in a purging process;
a first gas exhaust system connected to the reaction chamber, the first gas exhaust system comprising a first gas suction nozzle in the reaction chamber, the first gas exhaust system comprising a first pump outside the reaction chamber, the first gas suction nozzle being opposite to the gas supply nozzle with reference to the wafer boat, the first gas exhaust system performing exhausting operation in the deposition process, the first gas exhaust system being prohibited from performing exhausting operation in the purging process; and
a second gas exhaust system connected to an upper portion of the reaction chamber, the first gas exhaust system comprising a second pump outside the reaction chamber, the second gas exhaust system being prohibited from performing exhausting operation in the deposition process, the second gas exhaust system performing exhausting operation in the purging process.
